(19) United States
(12) Patent Application Publication
(10) Pub. No.: US 2024/0419880 A1
(43) Pub. Date: Dec. 19, 2024

(54) SCALABLE-LOGIC COVERAGE EVALUATION OF VERIFICATION TESTBENCHES

(71) Applicant: International Business Machines Corporation, Armonk, NY (US)

(72) Inventors: Bradley Donald Bingham, Austin, TX (US); Jason Raymond Baumgartner, Austin, TX (US); Viresh Paruthi, Austin, TX (US)

(21) Appl. No.: 18/211,520

(22) Filed: Jun. 19, 2023

(51) Int. Cl. G06F 30/33

(52) U.S. Cl. CPC G06F 30/33

(57) ABSTRACT

A computer-implemented method, system, and computer program product for applying scalable formal coverage analysis to a testbench. A set of properties proven unhittable in an original testbench is selected to be considered for coverage analysis. A gate (e.g., latch) of a device under test is selected and mutated, where the mutation includes utilizing a random value and where a mutation property for the set of selected properties proven unhittable is associated with the mutated gate of the device under test. It is then determined whether the mutation property is hittable or unhittable while the gate is mutated in order to determine whether the gate is covered by the selected properties. A gate is covered by the selected properties if the mutation property is hittable while the gate is mutated. Furthermore, a gate is uncovered by the selected properties if the mutation property is unhittable while the gate is mutated.

### TECHNICAL FIELD

The present disclosure relates generally to testbench verification, and more particularly to applying scalable formal coverage analysis to a testbench for which a property set can be formally proven without requiring customized verification algorithms.

### BACKGROUND

A testbench or testing workbench is an environment used to verify the correctness of a design or model. Such a design or model may be referred to as a design under test (“DUT”). Furthermore, a verification engineer may write a “driver” that characterizes the set of valid DUT input behaviors as well as a “checker” that tracks the DUT input and output behaviors to determine if the DUT is performing according to the design specification. The DUT, driver, and checker together form the testbench, which is subject to formal verification analysis.

### SUMMARY

In one embodiment of the present disclosure, a computer-implemented method for applying scalable formal coverage analysis to a testbench comprises selecting a set of properties proven unhittable in an original testbench to consider for coverage. The method further comprises selecting and mutating one or more gates of a device under test of the original testbench, where a mutation property for the set of properties is introduced for each mutated gate of the device under test. The method additionally comprises determining that a gate is covered in response to the mutation property being hittable while the gate is mutated. Furthermore, the method comprises determining that the gate is uncovered in response to the mutation property being unhittable while the gate is mutated.

Other forms of the embodiment of the computer-implemented method described above are in a system and in a computer program product.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates a communication system for practicing the principles of the present disclosure in accordance with an embodiment of the present disclosure;

FIG. 2 is a diagram of the software components used by the tester for applying formal coverage analysis to the testbench in accordance with an embodiment of the present disclosure;

FIG. 3 illustrates an embodiment of the present disclosure of the hardware configuration of the tester which is representative of a hardware environment for practicing the present disclosure;

FIG. 4 is a flowchart of a method for applying scalable formal coverage analysis to a testbench in accordance with an embodiment of the present disclosure;

FIG. 5 illustrates the selected mutation of a gate of a device under test of the testbench in accordance with an embodiment of the present disclosure;

FIG. 6 illustrates gated mutation coverage properties in accordance with an embodiment of the present disclosure;

FIG. 7 illustrates a mutation selection testbench in accordance with an embodiment of the present disclosure;

FIG. 8 is a flowchart of a method for logic transformation once a specific mutation is chosen in accordance with an embodiment of the present disclosure;

FIG. 9 illustrates property-implying unate input merging in accordance with an embodiment of the present disclosure;

FIG. 10 illustrates a two-model constrained testbench in accordance with an embodiment of the present disclosure; and

FIG. 11 is a flowchart of a method for applying scalable formal coverage analysis using the two-model constrained testbench of FIG. 10 in accordance with an embodiment of the present disclosure.

### DETAILED DESCRIPTION

As stated in the Background section, a testbench or testing workbench is an environment used to verify the correctness of a design or model. Such a design or model may be referred to as a design under test (“DUT”). Furthermore, a verification engineer may write a “driver” that characterizes the set of valid DUT input behaviors as well as a “checker” that tracks the DUT input and output behaviors to determine if the DUT is performing according to the design specification. The DUT, driver, and checker together form the testbench, which is subject to formal verification analysis.

In formal verification analysis, a set of properties (propositional logic formulas over testbench signals) as part of the checker are checked in connection with verifying the correctness of the DUT to determine if there are any property failures. If there is a property failure, it may be said that the property is demonstrated to be “incorrect” or “hittable.” If, however, the property did not fail, the property may be proven to be “correct” or “unhittable.”

After several iterations of correcting testbench errors (e.g., incorrect drivers driving illegal input scenarios and/or incorrect properties), then a testbench will often have all of its properties proven unhittable. A natural speculation is then whether the driver and checker suffice to cover all valid input scenarios and whether the correctness properties cover all relevant characteristics of the design. Such a verification as to whether the driver and checker suffice to cover all valid input scenarios and whether the correctness properties cover all relevant characteristics of the design is referred to as “coverage analysis.”

Formal coverage analysis tools have been developed in an attempt to determine whether the driver and checker suffice to cover all valid input scenarios and whether the correctness properties cover all relevant characteristics of the design. Unfortunately, such formal coverage analysis tools tend to consume dramatically more runtime than verifying the original testbench. Furthermore, such formal coverage analysis tools require customized verification algorithms, which is time-consuming to develop and limiting in that they do not support the full suite of synergistic algorithms available in state-of-the-art verification tools thus providing scalability limitations.

As a result, such formal coverage analysis tools are not scalable to be applied to any testbench for which a property-set can be formally proven. Furthermore, such formal coverage analysis tools require customized verification algorithms.

The embodiments of the present disclosure provide a means for applying a scalable formal coverage analysis to a testbench for which a property set can be formally proven without requiring customized verification algorithms by utilizing mutations and mutation selection logic. Each mutation may correspond to gates (e.g., latches) of the device under test which are “mutated.” “Mutation,” as used herein, refers to modifying the behavior of a gate. In one embodiment, mutation includes inputting a random value each cycle into a gate of the device under test, such as a latch. Mutation selection logic is used to select which gate of the design under test to mutate. A mutation property may be created for each mutation, where a determination is made as to whether the selected mutation causes the mutation property to be falsified, thereby indicating that the testbench covers the mutated gate. A gate may be deemed to be covered by the properties proven unhittable in the original testbench if the corresponding mutation property is hittable while the gate is mutated. A gate may be deemed to be uncovered by the properties proven unhittable in the original testbench if the mutation property is unhittable while the gate is mutated. A further description of these and other features will be provided below.

While the following discusses the present disclosure in connection with mutating gates, such as latches, the principles of the preset disclosure may also apply to mutating device under test input or output signals. A person of ordinary skill in the art would be capable of applying the principles of the present disclosure to such implementations. Furthermore, embodiments applying the principles of the present disclosure to such implementations would fall within the scope of the present disclosure.

In some embodiments of the present disclosure, the present disclosure comprises a computer-implemented method, system and computer program product for applying scalable formal coverage analysis to a testbench. In one embodiment of the present disclosure, a set of properties proven unhittable in an original testbench is selected to be considered for coverage. A gate (e.g., latch) of a device under test is selected and mutated, where the mutation may consist of utilizing a random value each cycle, and where a mutation property for the set of properties proven unhittable in the original testbench is introduced for the mutated gate (e.g., latch) of the device under test. It is then determined whether the mutation property is hittable or unhittable while the gate (e.g., latch) is mutated in order to determine whether the gate is covered by the property. A gate (referring to the gate of the device under test that is mutated) is covered by the testbench properties if the mutation property is hittable while the gate is mutated. Furthermore, a gate (referring to the gate of the device under test that is mutated) is uncovered by the testbench properties if the mutation property is unhittable while the gate is mutated. In this manner, a scalable formal coverage analysis is applied to a testbench without requiring customized verification algorithms.

In the following description, numerous specific details are set forth to provide a thorough understanding of the present disclosure. However, it will be apparent to those skilled in the art that the present disclosure may be practiced without such specific details. In other instances, well-known circuits have been shown in block diagram form in order not to obscure the present disclosure in unnecessary detail. For the most part, details considering timing considerations and the like have been omitted inasmuch as such details are not necessary to obtain a complete understanding of the present disclosure and are within the skills of persons of ordinary skill in the relevant art.

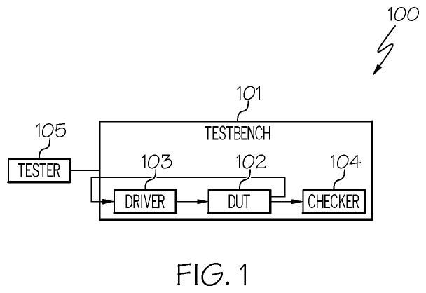

Referring now to the Figures in detail, FIG. 1 illustrates an embodiment of the present disclosure of a communication system 100 for practicing the principles of the present disclosure. Communication system 100 includes a testbench 101 corresponding to an environment used to verify the correctness of a device under test (“DUT”) 102. A verification engineer may write a driver 103 that characterizes the set of valid DUT input behaviors as well as a checker 104 that tracks the DUT input and output behavior to determine if DUT 102 is performing according to the design specification. As previously discussed, DUT 102, driver 103 and checker 104 together form testbench 101, which is subject to formal verification analysis performed by a tester 105 connected to testbench 101.

In one embodiment, tester 105 is configured to perform formal verification analysis on properties proven unhittable by testbench 101. “Properties,” as used herein, refer to propositional logic formulas over testbench signals. A property is deemed to be “hittable” if it is falsified, i.e., if a “counterexample trace” is found starting from an initial state showing an execution sequence of the testbench illustrating an assertion of the property. Otherwise, if the property is proven correct, i.e., it is demonstrated that no such counterexample trace exists, then it is called “unhittable.”

The “original properties,” as used herein, refer to those properties that are written as part of checker 104 of the original testbench 101 to determine adherence of DUT 102 to its design specification. If such original properties are unhittable, then DUT 102 is said to be performing correctly.

Checker 104 is deemed to fail if any of its associated properties are hittable and passes if all of its associated properties are unhittable.

As discussed below, the principles of the present disclosure are discussed herein in connection with a single original property. If multiple original properties are present, the original properties can be combined by expressing this single original property as their disjunction (i.e., the logical OR function).

“Mutation coverage properties” (or simply “coverage properties” or “mutation properties”), as used herein, refer to properties that are used to determine if a particular gate (e.g., latch) is covered by the original property or not.

In one embodiment, tester 105 is configured to perform single-gate mutation analysis, which seeks to partition the gates of DUT 102 into “covered” or “uncovered.” A gate (e.g., latch L) is “covered” if when mutating the gate (e.g., latch), such as replacing it with purely-nondeterministic or random behavior, the mutation causes any unhittable original property to become hittable. If, however, the properties remain unhittable when mutating the gate (e.g., latch), then the gate (e.g., latch) is “uncovered.” Such gates whose behavior are modified are referred to herein as mutations. “Mutation selection logic” can be used to select which gate among the multiple gates of DUT 102 will be mutated. In one embodiment, a distinct mutation property is introduced for each selectable mutation to discern if that mutated gate is covered.

In one embodiment, optionally, the mutation selection logic may be partitioned into sets that are associated, such as via a hardware description language (HDL) signal vector, where each set is called a “mutation group.” A mutation group of size k, when mutated, is simultaneously replaced with k independent nondeterministic inputs, and a single mutation property corresponds to the k-sized mutation. Such an approach can reduce the number of mutation properties though with a loss of coverage accuracy when coverage properties are hittable as it is unclear which of the k gates are covered.

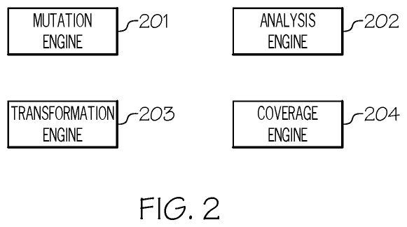

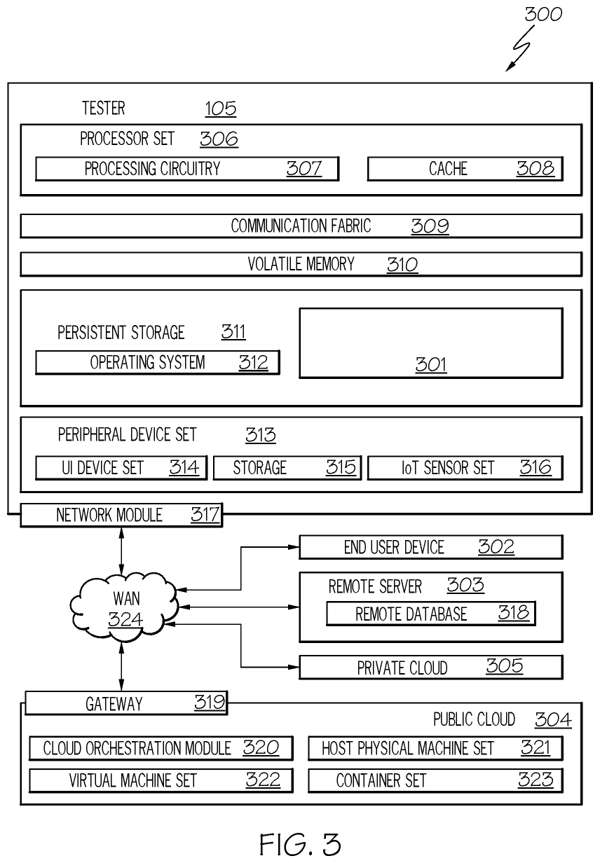

A more detailed description of these and other features will be provided further below. Furthermore, a description of the software components of tester 105 is provided below in connection with FIG. 2 and a description of the hardware configuration of tester 105 is provided further below in connection with FIG. 3.

System 100 is not to be limited in scope to any one particular network architecture. System 100 may include any number of testbenches 101, and testers 105.

Referring now to FIG. 2, in conjunction with FIG. 1, FIG. 2 is a diagram of the software components used by tester 105 for applying formal coverage analysis to testbench 101 in accordance with an embodiment of the present disclosure.

As shown in FIG. 2, tester 105 includes a mutation engine 201 configured to select a set of properties that were proven unhittable in an original testbench (e.g., testbench 101) to be considered for coverage.

Furthermore, mutation engine 201 is configured to select and mutate a gate (e.g., latch) of DUT 102, where the mutation includes utilizing a random value each cycle and where a mutation property for the set of testbench properties is introduced into the gate of DUT 102. Such a gate (e.g., latch) is mutated to determine if the gate is covered by the mutation property introduced for the mutated gate.

Furthermore, tester 105 includes an analysis engine 202 configured to determine that the gate (referring to the gate of DUT 102 that is mutated) is covered by the testbench properties in response to the mutation property being hittable while the gate is mutated. Additionally, analysis engine 202 is configured to determine that such a gate is uncovered by the testbench properties in response to the mutation property being unhittable while the gate is mutated.

Additionally, tester 105 includes a transformation engine 203 configured to implement a highly-scalable logic transformation that enables efficient solution of mutation properties.

Furthermore, tester 105 includes a coverage engine 204 configured to determine if a gate (e.g., latch) is or is not covered by the original properties utilizing a two-model constrained testbench.

A further description of these and other features is provided below in connection with the discussion of the method for applying scalable formal coverage analysis to a testbench.

Prior to the discussion of the method for applying scalable formal coverage analysis to a testbench, a description of the hardware configuration of tester 105 (FIG. 1) is provided below in connection with FIG. 3.

Referring now to FIG. 3, in conjunction with FIG. 1, FIG. 3 illustrates an embodiment of the present disclosure of the hardware configuration of tester 105 which is representative of a hardware environment for practicing the present disclosure.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 300 contains an example of an environment for the execution of at least some of the computer code 301 involved in performing the inventive methods, such as applying scalable formal coverage analysist to a testbench. In addition to block 301, computing environment 300 includes, for example, tester 105, network 324, such as a wide area network (WAN), end user device (EUD) 302, remote server 303, public cloud 304, and private cloud 305. In this embodiment, tester 105 includes processor set 306 (including processing circuitry 307 and cache 308), communication fabric 309, volatile memory 310, persistent storage 311 (including operating system 312 and block 301, as identified above), peripheral device set 313 (including user interface (UI) device set 314, storage 315, and Internet of Things (IoT) sensor set 316), and network module 317. Remote server 303 includes remote database 318. Public cloud 304 includes gateway 319, cloud orchestration module 320, host physical machine set 321, virtual machine set 322, and container set 323.

Tester 105 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 318. As is well understood in the art of computer technology, and depending upon the technology, performance of a computer-implemented method may be distributed among multiple computers and/or between multiple locations. On the other hand, in this presentation of computing environment 300, detailed discussion is focused on a single computer, specifically tester 105, to keep the presentation as simple as possible. Tester 105 may be located in a cloud, even though it is not shown in a cloud in FIG. 3. On the other hand, tester 105 is not required to be in a cloud except to any extent as may be affirmatively indicated.

Processor set 306 includes one, or more, computer processors of any type now known or to be developed in the future. Processing circuitry 307 may be distributed over multiple packages, for example, multiple, coordinated integrated circuit chips. Processing circuitry 307 may implement multiple processor threads and/or multiple processor cores. Cache 308 is memory that is located in the processor chip package(s) and is typically used for data or code that should be available for rapid access by the threads or cores running on processor set 306. Cache memories are typically organized into multiple levels depending upon relative proximity to the processing circuitry. Alternatively, some, or all, of the cache for the processor set may be located “off chip.” In some computing environments, processor set 306 may be designed for working with qubits and performing quantum computing.

Computer readable program instructions are typically loaded onto tester 105 to cause a series of operational steps to be performed by processor set 306 of tester 105 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 308 and the other storage media discussed below. The program instructions, and associated data, are accessed by processor set 306 to control and direct performance of the inventive methods. In computing environment 300, at least some of the instructions for performing the inventive methods may be stored in block 301 in persistent storage 311.

Communication fabric 309 is the signal conduction paths that allow the various components of tester 105 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 310 is any type of volatile memory now known or to be developed in the future. Examples include dynamic type random access memory (RAM) or static type RAM. Typically, the volatile memory is characterized by random access, but this is not required unless affirmatively indicated. In tester 105, the volatile memory 310 is located in a single package and is internal to tester 105, but, alternatively or additionally, the volatile memory may be distributed over multiple packages and/or located externally with respect to tester 105.

Persistent Storage 311 is any form of non-volatile storage for computers that is now known or to be developed in the future. The non-volatility of this storage means that the stored data is maintained regardless of whether power is being supplied to tester 105 and/or directly to persistent storage 311. Persistent storage 311 may be a read only memory (ROM), but typically at least a portion of the persistent storage allows writing of data, deletion of data and re-writing of data. Some familiar forms of persistent storage include magnetic disks and solid state storage devices. Operating system 312 may take several forms, such as various known proprietary operating systems or open source Portable Operating System Interface type operating systems that employ a kernel. The code included in block 301 typically includes at least some of the computer code involved in performing the inventive methods.

Peripheral device set 313 includes the set of peripheral devices of tester 105. Data communication connections between the peripheral devices and the other components of tester 105 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 314 may include components such as a display screen, speaker, microphone, wearable devices (such as goggles and smart watches), keyboard, mouse, printer, touchpad, game controllers, and haptic devices. Storage 315 is external storage, such as an external hard drive, or insertable storage, such as an SD card. Storage 315 may be persistent and/or volatile. In some embodiments, storage 315 may take the form of a quantum computing storage device for storing data in the form of qubits. In embodiments where tester 105 is required to have a large amount of storage (for example, where tester 105 locally stores and manages a large database) then this storage may be provided by peripheral storage devices designed for storing very large amounts of data, such as a storage area network (SAN) that is shared by multiple, geographically distributed computers. IoT sensor set 316 is made up of sensors that can be used in Internet of Things applications. For example, one sensor may be a thermometer and another sensor may be a motion detector.

Network module 317 is the collection of computer software, hardware, and firmware that allows tester 105 to communicate with other computers through WAN 324. Network module 317 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 317 are performed on the same physical hardware device. In other embodiments (for example, embodiments that utilize software-defined networking (SDN)), the control functions and the forwarding functions of network module 317 are performed on physically separate devices, such that the control functions manage several different network hardware devices. Computer readable program instructions for performing the inventive methods can typically be downloaded to tester 105 from an external computer or external storage device through a network adapter card or network interface included in network module 317.

WAN 324 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 302 is any computer system that is used and controlled by an end user (for example, a customer of an enterprise that operates tester 105), and may take any of the forms discussed above in connection with tester 105. EUD 302 typically receives helpful and useful data from the operations of tester 105. For example, in a hypothetical case where tester 105 is designed to provide a recommendation to an end user, this recommendation would typically be communicated from network module 317 of tester 105 through WAN 324 to EUD 302. In this way, EUD 302 can display, or otherwise present, the recommendation to an end user. In some embodiments, EUD 302 may be a client device, such as thin client, heavy client, mainframe computer, desktop computer and so on.

Remote server 303 is any computer system that serves at least some data and/or functionality to tester 105. Remote server 303 may be controlled and used by the same entity that operates tester 105. Remote server 303 represents the machine(s) that collect and store helpful and useful data for use by other computers, such as tester 105. For example, in a hypothetical case where tester 105 is designed and programmed to provide a recommendation based on historical data, then this historical data may be provided to tester 105 from remote database 318 of remote server 303.

Public cloud 304 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 304 is performed by the computer hardware and/or software of cloud orchestration module 320. The computing resources provided by public cloud 304 are typically implemented by virtual computing environments that run on various computers making up the computers of host physical machine set 321, which is the universe of physical computers in and/or available to public cloud 304. The virtual computing environments (VCEs) typically take the form of virtual machines from virtual machine set 322 and/or containers from container set 323. It is understood that these VCEs may be stored as images and may be transferred among and between the various physical machine hosts, either as images or after instantiation of the VCE. Cloud orchestration module 320 manages the transfer and storage of images, deploys new instantiations of VCEs and manages active instantiations of VCE deployments. Gateway 319 is the collection of computer software, hardware, and firmware that allows public cloud 304 to communicate through WAN 324.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 305 is similar to public cloud 304, except that the computing resources are only available for use by a single enterprise. While private cloud 305 is depicted as being in communication with WAN 324 in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 304 and private cloud 305 are both part of a larger hybrid cloud.

Block 301 further includes the software components discussed herein in connection with FIGS. 2 and 4-11 to apply scalable formal coverage analysis to a testbench. In one embodiment, such components may be implemented in hardware. The functions discussed above performed by such components are not generic computer functions. As a result, tester 105 is a particular machine that is the result of implementing specific, non-generic computer functions.

In one embodiment, the functionality of such software components of tester 105, including the functionality for applying scalable formal coverage analysis to a testbench, may be embodied in an application specific integrated circuit.

As stated above, in formal verification analysis, a set of properties (propositional logic formulas over testbench signals) as part of the checker are checked in connection with verifying the correctness of the DUT to determine if there are any property failures. If there is a property failure, it may be said that the property is demonstrated to be “incorrect” or “hittable.” If, however, the property did not fail, the property may be proven to be “correct” or “unhittable.” After several iterations of correcting testbench errors (e.g., incorrect drivers driving illegal input scenarios and/or incorrect properties), then a testbench will often have all of its properties proven unhittable. A natural speculation is then whether the driver and checker suffice to cover all valid input scenarios and whether the correctness properties cover all relevant characteristics of the design. Such a verification as to whether the driver and checker suffice to cover all valid input scenarios and whether the correctness properties cover all relevant characteristics of the design is referred to as “coverage analysis.” Formal coverage analysis tools have been developed in an attempt to determine whether the driver and checker suffice to cover all valid input scenarios and whether the correctness properties cover all relevant characteristics of the design. Unfortunately, such formal coverage analysis tools tend to consume dramatically more runtime than verifying the original testbench. Furthermore, such formal coverage analysis tools require customized verification algorithms, which is time-consuming to develop and limiting in that they do not support the full suite of synergistic algorithms available in state-of-the-art verification tools thus providing scalability limitations. As a result, such formal coverage analysis tools are not scalable to be applied to any testbench for which a property-set can be formally proven.

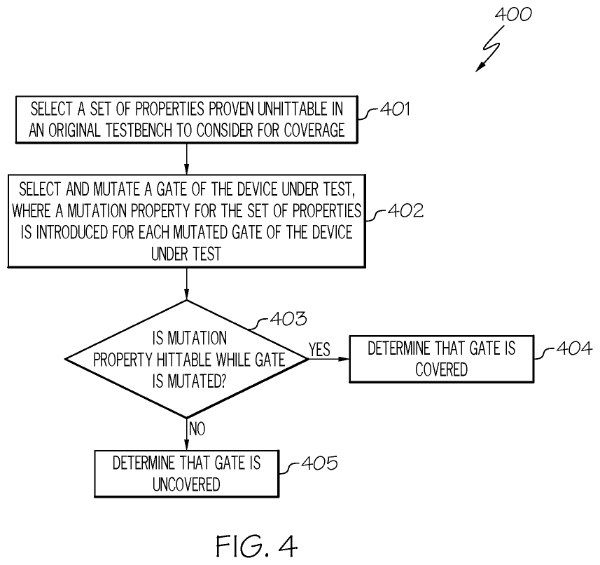

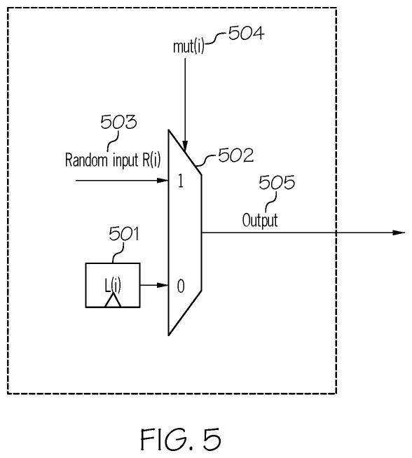

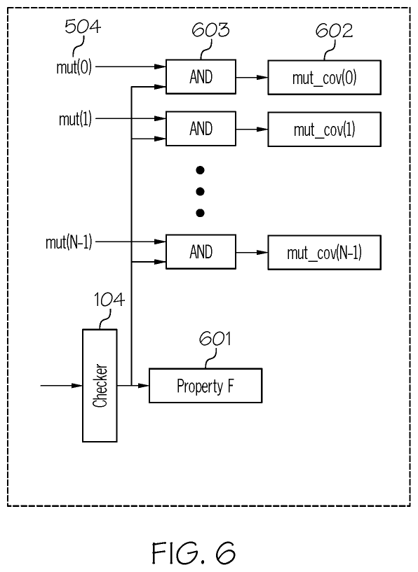

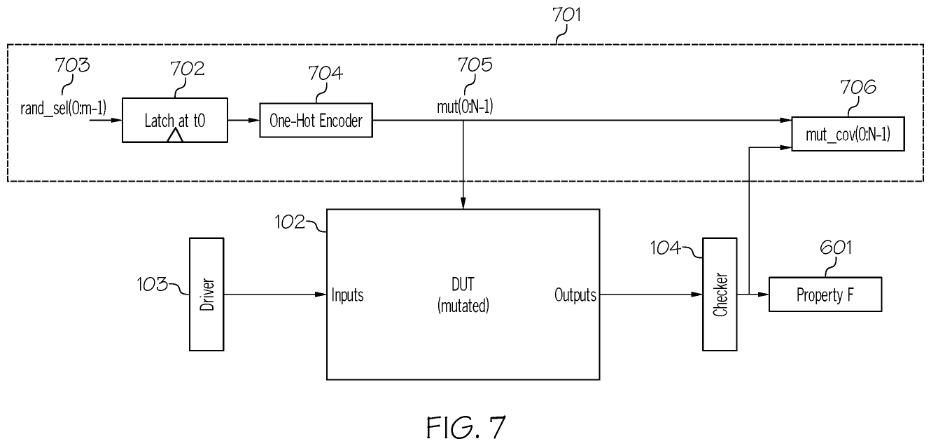

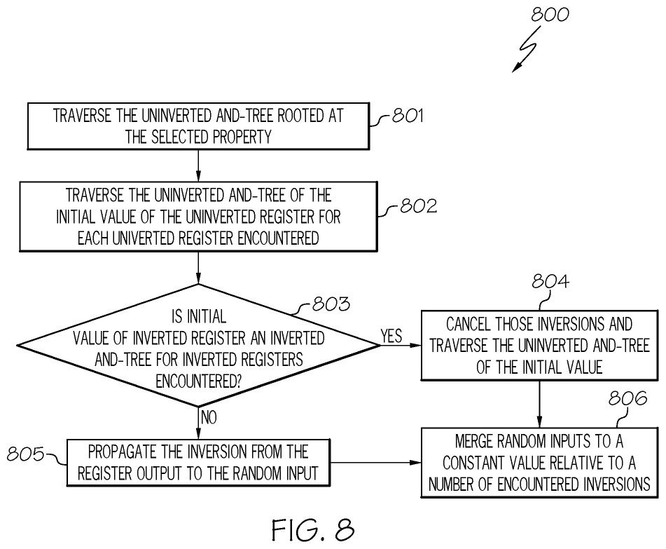

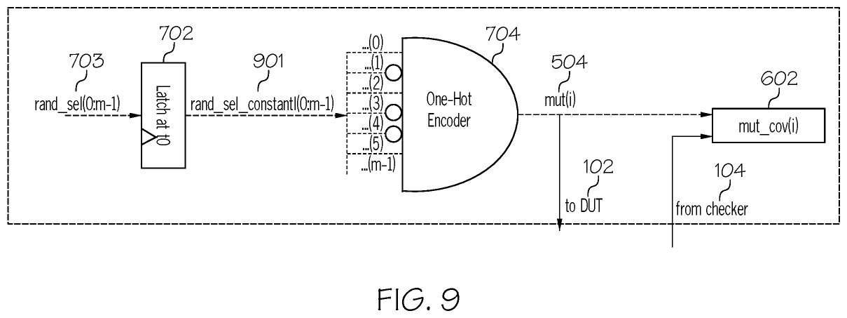

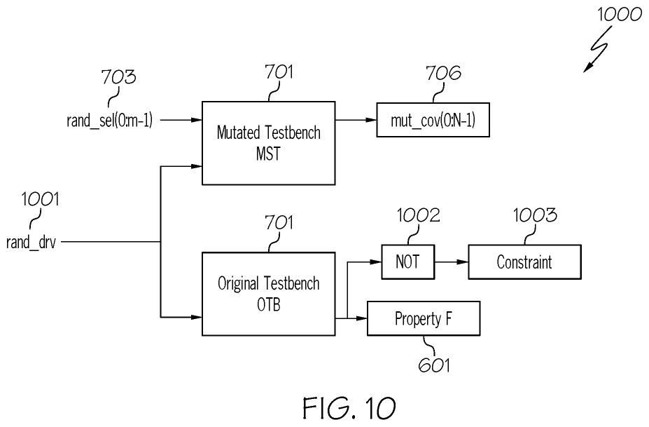

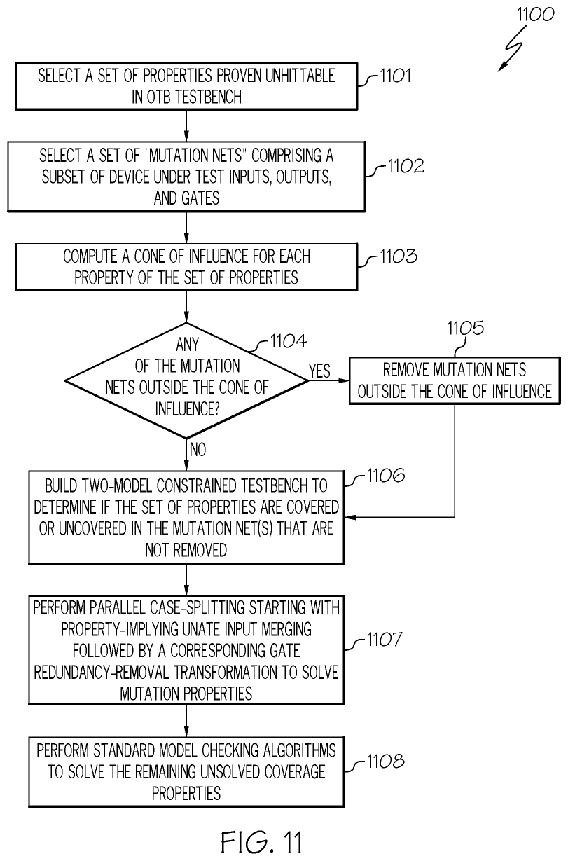

The embodiments of the present disclosure provide a means for applying scalable formal coverage analysis to a testbench without requiring customized verification algorithms as discussed below in connection with FIGS. 4-11. FIG. 4 is a flowchart of a method for applying scalable formal coverage analysis to a testbench. FIG. 5 illustrates the selected mutation of a gate of a device under test of the testbench. FIG. 6 illustrates gated mutated coverage properties. FIG. 7 illustrates a mutation selection testbench. FIG. 8 is a flowchart of a method for logic transformation once a specific mutation is chosen. FIG. 9 illustrates property-implying unate input merging. FIG. 10 illustrates a two-model constrained testbench. FIG. 11 is a flowchart of a method for applying scalable formal coverage analysis using the two-model constrained testbench of FIG. 10.

As stated above, FIG. 4 is a flowchart of a method 400 for applying scalable formal coverage analysis to a testbench in accordance with an embodiment of the present disclosure.

Referring to FIG. 4, in conjunction with FIGS. 1-3, in operation 401, mutation engine 201 of tester 105 selects a set of properties proven unhittable in an original testbench (e.g., testbench 101) to consider for coverage.

In operation 402, mutation engine 201 of tester 105 selects and mutates a gate (e.g., latch) of DUT 102, where the mutation includes utilizing a random value each cycle and where a mutation property for the set of properties proven unhittable is introduced for each mutated gate (e.g., latch) of DUT 102.

In operation 403, analysis engine 202 of tester 105 determines whether the mutation property is hittable or unhittable while the gate (e.g., latch) is mutated in order to determine whether the gate is covered.

As discussed above, a gate (referring to the gate of DUT 102 that is mutated along with having a mutation property for the set of properties proven unhittable in an original testbench (e.g., testbench 101) being introduced into said gate) is covered by the testbench properties if the mutation property is hittable while the gate is mutated. Furthermore, as discussed above, a gate (referring to the gate of DUT 102 that is mutated along with having a mutation property for the set of properties proven unhittable in an original testbench (e.g., testbench 101) being introduced into said gate) is uncovered by the testbench properties if the mutation property is unhittable while the gate is mutated.

If the mutation property is hittable while the gate (e.g., latch) is mutated, then, in operation 404, analysis engine 404 of tester 105 determines that the gate (e.g., latch) is covered.

If, however, the mutation property is not hittable (i.e., the mutation property is unhittable) while the gate (e.g., latch) is mutated, then, in operation 405, analysis engine 404 of tester 105 determines that the gate (e.g., latch) is not covered.

A more detailed discussion regarding method 400 is provided below.

In one embodiment, in order for mutation engine 201 to “mutate” each of the N gates in DUT 102 of testbench 101, each gate (e.g., latch L(i)) is augmented with a multiplexer (“mux”) selection logic, selecting between the original output of L(i) and a unique random input. In one embodiment, such a selection depends on the assertion or non-assertion of the control signal, mut_sel(i), where mut_sel(0:N−1) is a one-hot signal indicating the unique latch L(i) is mutated, as shown in FIG. 5.

FIG. 5 illustrates the selected mutation of a gate (e.g., latch) of DUT 102 of testbench 101 in accordance with an embodiment of the present disclosure.

Referring to FIG. 5, the gate to be mutated, such as latch 501 (L(i)), is augmented with a multiplexer 502. Multiplexer 502 receives a random input R(i) 503 as well as an output of the gate, such as latch 501 (L(i)). In one embodiment, upon asserting a control signal, mut(i) (also referred to as “mut_sel(i)”) 504, to multiplexer 502, random input 503 drives an output 505 of multiplexer 502. In one embodiment, upon not asserting control signal 504 to multiplexer 502, the output of latch 501 (L(i)) drives output 505 of multiplexer 502.

In one embodiment, the original property F (a property from the set of properties proven unhittable in an original testbench (e.g., testbench 101)) is replicated N times, one for each possible mutation gate (e.g., latch), where there are N gates (e.g., latches) in DUT 102. Each replication is referred to as a “mutation property” used to assess whether the mutation causes a testbench property to fail, and thus whether the mutated gate is “covered” by testbench properties. As shown in FIG. 6, the original property F 601 is replicated N times and gated by the appropriate bit of mut_sel 504.

Referring to FIG. 6, FIG. 6 illustrates gated mutation coverage properties in accordance with an embodiment of the present disclosure.

As shown in FIG. 6, property F 601 is replicated N times as mut_cov(0) . . . mut_cov(N−1) 602. Furthermore, mut_cov(i) 602 is asserted when F AND mut(i) 504 are both true, as shown via the AND logic gates 603. That is, property F 601 is hit when L(i) is mutated.

In one embodiment, the outputs of mut_cov(i) 602 are combined into a vector of N mutation properties mut_cov(0:N−1) 706 as shown in FIG. 7, which is discussed further below.

Referring to FIG. 7, FIG. 7 illustrates a mutation selection testbench 701 in accordance with an embodiment of the present disclosure.

As shown in FIG. 7, mutation selection testbench (MST) 701 includes “Latch at time=0” 702 which receives an input of rand_sel(0:m−1) 703 at time zero and then holds that sampled value forever and outputs to one-hot encoder 704. One-hot encoding is used for indicating the state of latch 702, specifically selecting which of the N mutations will apply. The output of one-hot encoder 704 is mut(0:N−1) 705 which is inputted into DUT 102. Furthermore, as shown in FIG. 7, mut(0:N−1) 705 and property F 601 are inputted into mut_cov(0:N−1) 706.

In one embodiment, given N as the number of testbench latches to consider for mutation, let m=ceiling(log_2 N). Then m is the number of bits needed to represent values 0, 1, . . . , N−1 in decimal encoding. In one embodiment, a random input vector of length m is added to the mutation testbench, along with a vector of gates (e.g., latches) of length m which is initialized by this random input vector. In one embodiment, these gates (e.g., latches) hold their initial value forever (“Latch at t0” 702 in FIG. 7). These gates (e.g., latches) effectively remember the selection of which gate (e.g., latch) to mutate across time-steps. This decimal-encoded randomly-selected value is then encoded as the one-hot vector mut_sel 504.

It is noted that if N is not a power of 2, there are values of rand_sel (see 703 of FIG. 7) greater than N. In such an embodiment, for such values of rand_sel greater than N, no bit of mut_sel 504 will be 1 and no gate (e.g., latch 501) is selected for mutation. In any given sequential execution of testbench 101, at most one gate (e.g., latch L(i) 501) is selected for mutation, and only the corresponding mut_cov(i) (see 602) coverage property is possibly hittable due to that mutation. The other mut_cov(j) (see 602) coverage properties for j different from i cannot be hittable when gate (e.g., latch L(i) 501) is mutated, due to gating conjunction of these coverage properties.

In one embodiment, the mutation selection logic, latch mutation logic and coverage property additions are injected into the original testbench (OTB) 101 to form the mutated selection testbench (MST) 701 of FIG. 7. By construction, running the MST 701 as-is with formal verification tools will determine the coverage of any gate (e.g., latch) for which the corresponding mut_cov property (see 602) is solved.

In one embodiment, all mutations are injected into the same testbench (e.g., testbench 101). As a result of implementing such an embodiment, a single testbench compile and import is reused across all mutations. Testbench compilation consumes significant runtime, especially if performed thousands of times for thousands of candidate mutations. Furthermore, most “orchestration” flows begin with lighter logic reduction techniques before heavier reductions and solving algorithms are used. Such an orchestration configuration can be reused across all mutations.

In one embodiment, after compile, import, and lighter logic reductions, a case-split on each mut_cov property (see 602) occurs so that each is solved independently. These cases can be solved in parallel or serially. In one embodiment, each property is solved independently. As previously discussed, each mut_cov(i) property (see 602) conjuncts with the mutation selection logic, and is hittable if and only if a mutation is enabled solely at the gate (e.g., latch L(i) 501). In one embodiment, the decision of which gate (e.g., latch) to mutate is made once and remembered across all time-steps. After case-splitting on each property, it thus is the case that only a single mutation can be enabled.

In one embodiment, a technique for highly-scalable logic transformation that enables property-specific mutation is discussed below in connection with FIG. 8.

FIG. 8 is a flowchart of a method 800 for logic transformation once a specific mutation is chosen in accordance with an embodiment of the present disclosure. In one embodiment, such a technique utilizes the and-inventor graph (AIG) netlist representation. An and-inverter graph (AIG) is a directed graph that represents a structural implementation of the logical functionality of a circuit or network. An AIG consists of two-input nodes representing logical conjunction, edges optionally containing markers indicating logical negation, and state-holding gates, such as latches or registers. Non-state-holding gates, such as AND gates, are referred to as “combinational gates.”

Referring to FIG. 8, in operation 801, transformation engine 203 of tester 105 traverses the uninverted AND-tree rooted at the selected property.

In operation 802, for each uninverted register encountered in operation 801, if said registers hold their initial value forever (i.e., if their next-state functions hold their current values), transformation engine 203 of tester 105 traverses the uninverted AND-tree of the initial value of that register (which may be a single random input). Any uninverted (or inverted) random inputs encountered can be merged to constant-ONE (if inverted, to constant-ZERO).

In operation 803, for any inverted registers encountered in operation 801, if said registers hold their initial value forever (i.e., if their next-state functions hold their current values), transformation engine 203 of tester 105 determines if their initial value is an inverted AND-tree.

If their initial value is an inverted AND-tree, then, in operation 804, transformation engine 203 of tester 105 cancels those inversions and traverses the uninverted AND-tree of the initial value.

If, however, the initial value of the inverted registers encountered in operation 801 is not an inverted AND-tree, such as a possibly-inverted random input, then, in operation 805, transformation engine 203 of tester 105 propagates the inversion from the register output to the random input.

Upon canceling the inversions in operation 804 or propagating the inversion in operation 805, in operation 806, transformation engine 203 of tester 105 merges the random inputs to a constant value relative to a number of encountered inversions. That is, transformation engine 203 merges the random inputs to a constant-ZERO or ONE value relative to encountering through an even or odd number of inversions, respectively.

In one embodiment, if this transformation is applied in the presence of multiple properties, merging of random inputs to constants is deferred and limited only to those compatibly encountered across every property.

The transformation performed by method 800 is referred to herein as “property-implying unate input merging.” An illustration of property-implying unate input merging is provided in FIG. 9. “Unate,” as used herein, refers to a rising edge going into a logic that can only cause a rising edge on the output of the logic and vice-versa.

Referring to FIG. 9, FIG. 9 illustrates property-implying unate input merging in accordance with an embodiment of the present disclosure.

As shown in FIG. 9, the unate path is from mut_cov(i) 602 to inputs rand_sel (0:m−1) 703 through one hot encoder 704 and latch 702. In one embodiment, one hot encoder 704 is a logical AND gate, which is used for checking for specific valuations to the “constant” latched version of rand_sel_constant(0:m−1) 901. In one embodiment, the unate path over rand_sel_constant( ) 901 enables property-implying unate input merging regardless of the DUT logic between the lower input path from mut_cov(i) 602 through DUT 102 to mut(i) 504, which generally is not unate.

Furthermore, regardless of the fact that the merged inputs rand_sel( ) 703 (see FIG. 7) also sensitize the mutation, which affects design logic and coverage property evaluation: if rand_sel( ) 703 took any other value, this selected coverage property would be trivially unhittable due to the gating condition. This transform thus preserves any property hit. In one embodiment, one-hot encoding is synthesized as an AND tree, checking whether the encoded vector evaluates to a certain value.

The approach of method 800 accelerates scalability in that each property can run in isolation. Resource-constrained results are valuable to end-to-end runtime. If a time limit T seconds is set using P threads, each property case-split can be limited to run for approximately B=T*P/N seconds before reporting as “unsolved” or before utilizing a heavier verification strategy for the most-difficult tiny percentage of mutation properties.

The fact that original property F (e.g., property F 601) has been proven unhittable in the original testbench (e.g., testbench 101) can be exploited to speed up solving of most properties as discussed below in connection with FIG. 10.

FIG. 10 illustrates a two-model constrained testbench 1000 in accordance with an embodiment of the present disclosure.

As illustrated in FIG. 10, two-model constrained testbench 1000 includes a mutated testbench (MST) 701 and an original testbench (OTB), such as testbench 101. Furthermore, as shown in FIG. 10, the random inputs (rand_drv 1001) to MST testbench 701 and OTB testbench 101 is driven identically, the rand_sel input 703 to MST testbench 701 is driven randomly and independently, and the original property is constrained to be unhittable in OTB testbench 101. That is, MST testbench 701 and OTB testbench 101 are driving identically except for rand_sel 703 which only applies to MST testbench 701. Furthermore, OTB testbench 101 is constrained to not hit property F 601 as shown via the NOT gate 1002 and constraint 1003.

This two-model testbench of FIG. 10 lends itself to very fast proofs of most unhittable coverage properties, relative to the runtime to solve the original property as unhittable in OTB testbench 101.

In one embodiment, OTB testbench 101 and MST testbench 701 have 1:1 corresponded gates, aside from the mutation logic in MST testbench 701. By using a two-model corresponding-gate accelerated redundancy-removal algorithm after performing the constraint-style optimization above, only a single mutation is present in MST testbench 701, and often many gates (e.g., latches) will be redundant across these two models. By quickly merging these equivalent gates (e.g., latches) using a highly-tuned redundancy removal engine, the constraint present in MST testbench 701 becomes a constraint over OTB testbench 101, thereby accelerating the verification of most properties.

Referring now to FIG. 11, FIG. 11 illustrates a method for applying scalable formal coverage analysis using the two-model constrained testbench of FIG. 10 in accordance with an embodiment of the present disclosure.

Referring to FIG. 11, in conjunction with FIGS. 1-10, in operation 1101, coverage engine 204 of tester 105 selects a set of properties proven unhittable in OTB testbench 101, such as F1, F2, . . . Fk, where k is a positive integer number. Furthermore, as previously discussed, a property F (e.g., property F 601) out of the set of properties is selected, such as F=F1.

In operation 1102, coverage engine 204 of tester 105 selects a set of “mutation nets” comprising a subset of device under test inputs, outputs, and gates. A “mutation net,” as used herein, refers to a grouping of test inputs, outputs, and gates. In one embodiment, such mutation nets are partitioned into mutation groups.

In operation 1103, coverage engine 204 of tester 105 computes a cone of influence for each property (mutation property) of the set of properties. A cone of influence, as used herein, refers to the set of gates reachable via fanin traversal of the testbench properties selected in operation 1101. In one embodiment, the cone of influence is computed by reaching the gates sourcing input pins of the property gates, then the gates sourcing input pins of those source gates, until all fanin gates have been encountered.

In operation 1104, coverage engine 204 of tester 105 determines whether any of the mutation nets are outside the cone of influence.

If any of the mutation nets are outside the cone of influence, then, in operation 1105, coverage engine 204 of tester 105 removes such mutation nets. This optimization is possible because such outside of cone of influence gates cannot affect the behavior of the selected testbench properties, and thus mutations of those gates cannot hit any mutation coverage properties.

If, however, there are no mutation nets outside the cone of influence, or after removing the mutation nets outside the cone of influence, in operation 1106, coverage engine 204 of tester 105 builds two-model constrained testbench 1000 as shown in FIG. 10 to determine if the set of properties are covered or uncovered in the mutation net(s) that are not removed.

In one embodiment, MST testbench 701 of two-model constrained testbench 1000 mutates a gate. In one embodiment, MST testbench 701 implements an N-way case split to solve each mutation property separately, where N corresponds to the number of mutated gates or mutation groups of DUT 102. Furthermore, as discussed above, in one embodiment, a mutation property for the set of selected properties is introduced for each mutated gate (e.g., latch 501) of DUT 102, where the mutated gate is augmented with a multiplexer (e.g., multiplexer 502) which receives a random input (e.g., random input 503) and an output of the gate (e.g., latch 501) correlated with the mutation property. Upon asserting the control signal (e.g., mut(i) 504), the random input (random input 503) drives an output of the multiplexer (e.g., multiplexer 502). Upon not asserting the control signal (e.g., mut(i) 504), the output of the gate (e.g., latch 501) introduced with the property drives the output of the multiplexer (e.g., multiplexer 502). The mutation property is conjuncted with the control signal, and thus can only assert when the mutation is sensitized at the multiplexer (e.g., multiplexer 502).

In operation 1107, parallel case-splitting (previously discussed) is performed starting with property-implying unate input merging followed by a corresponding gate redundancy-removal transformation to solve mutation properties. Based on performing parallel case-splitting, most coverage properties are solved.

In operation 1108, for the remaining unsolved coverage properties, coverage engine 204 utilizes standard model checking algorithms (e.g., FuseIC3, IVC, etc.) to solve the remaining unsolved coverage properties. In one embodiment, the orchestration flow that was effective to prove the properties originally on OTB testbench 101 are injected at this point.

In one embodiment, if further unsolved coverage properties remain, then a property decomposition algorithm that separately considers the set of original testbench properties selected in operation 1101 rather than disjuncting them into a single mutation property may be utilized to solve the unsolved coverage properties.

In one embodiment, if further unsolved coverage properties remain, including unsolved mutation groups, then such unsolved mutation groups are divided into individuation mutations followed by computing the cone of influence for each property of the set of properties as discussed above.

In this manner, a scalable formal coverage analysis is applied to a testbench for which a property set can be formally proven without requiring customized verification algorithms.

Furthermore, the principles of the present disclosure improve the technology or technical field involving testbench verification.

As discussed above, in formal verification analysis, a set of properties (propositional logic formulas over testbench signals) as part of the checker are checked in connection with verifying the correctness of the DUT to determine if there are any property failures. If there is a property failure, it may be said that the property is demonstrated to be “incorrect” or “hittable.” If, however, the property did not fail, the property may be proven to be “correct” or “unhittable.” After several iterations of correcting testbench errors (e.g., incorrect drivers driving illegal input scenarios and/or incorrect properties), then a testbench will often have all of its properties proven unhittable. A natural speculation is then whether the driver and checker suffice to cover all valid input scenarios and whether the correctness properties cover all relevant characteristics of the design. Such a verification as to whether the driver and checker suffice to cover all valid input scenarios and whether the correctness properties cover all relevant characteristics of the design is referred to as “coverage analysis.” Formal coverage analysis tools have been developed in an attempt to determine whether the driver and checker suffice to cover all valid input scenarios and whether the correctness properties cover all relevant characteristics of the design. Unfortunately, such formal coverage analysis tools tend to consume dramatically more runtime than verifying the original testbench. Furthermore, such formal coverage analysis tools require customized verification algorithms, which is time-consuming to develop and limiting in that they do not support the full suite of synergistic algorithms available in state-of-the-art verification tools thus providing scalability limitations. As a result, such formal coverage analysis tools are not scalable to be applied to any testbench for which a property-set can be formally proven.

Embodiments of the present disclosure improve such technology by selecting a set of properties proven unhittable in an original testbench to be considered for coverage. A gate (e.g., latch) of a device under test is selected and mutated, where the mutation may consist of utilizing a random value each cycle, and where a mutation property for the set of properties proven unhittable in the original testbench is introduced for the mutated gate (e.g., latch) of the device under test. It is then determined whether the mutation property is hittable or unhittable while the gate (e.g., latch) is mutated in order to determine whether the gate is covered by the property. A gate (referring to the gate of the device under test that is mutated) is covered by the testbench properties if the mutation property is hittable while the gate is mutated. Furthermore, a gate (referring to the gate of the device under test that is mutated) is uncovered by the testbench properties if the mutation property is unhittable while the gate is mutated. In this manner, a scalable formal coverage analysis is applied to a testbench without requiring customized verification algorithms. Furthermore, in this manner, there is an improvement in the technical field involving testbench verification.

The technical solution provided by the present disclosure cannot be performed in the human mind or by a human using a pen and paper. That is, the technical solution provided by the present disclosure could not be accomplished in the human mind or by a human using a pen and paper in any reasonable amount of time and with any reasonable expectation of accuracy without the use of a computer.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A computer-implemented method for applying scalable formal coverage analysis to a testbench, the method comprising:
selecting a set of properties proven unhittable in an original testbench to consider for coverage;
selecting and mutating one or more gates of a device under test of said original testbench, wherein a mutation property for said set of properties is introduced for each mutated gate of said device under test;
determining that a gate is covered in response to said mutation property being hittable while said gate is mutated; and
determining that said gate is uncovered in response to said mutation property being unhittable while said gate is mutated.

2. The method as recited in claim 1, wherein a multiplexer is introduced between said gate and fan-out logic, wherein said multiplexer receives a random input and an output of said gate, wherein upon asserting a control signal to said multiplexer, said random input drives an output of said multiplexer thereby enabling mutation, wherein upon not asserting said control signal to said multiplexer, said output of said gate drives said output of said multiplexer.

3. The method as recited in claim 2, wherein said set of properties is replaced for each mutated gate of said device under test and conjuncted with said control signal to enable said mutation.

4. The method as recited in claim 1 further comprising:
selecting a set of mutation nets comprising a subset of device under test inputs, outputs and gates;
computing a cone of influence for each mutation property of said set of properties;
removing one or more mutation nets of said set of mutation nets that are outside said cone of influence; and
building a two-model testbench to determine if said set of properties are covered in one or more mutation nets of said set of mutation nets that are not removed, wherein said two-model testbench comprises a first testbench for mutating a gate and a second testbench corresponding to said original testbench.

5. The method as recited in claim 1, wherein mutation-selection logic statically nondeterministically selects among a set of possible mutations, wherein said selection is implemented by generating a random input vector to initialize a register vector that holds its value forever, which in turn is encoded as a one-hot vector, wherein each one-hot bit drives a control signal to multiplexors associated with said mutations.

6. The method as recited in claim 1 further comprising:
traversing an uninverted AND-tree rooted at a selected property;
traversing said uninverted AND-tree of an initial value of a register for each uninverted register encountered in said traversing of said uninverted AND-tree rooted at said selected property; and
determining if said initial value is an inverted AND-tree for each inverted register encountered in said traversing of said uninverted AND-tree rooted at said selected property.

7. The method as recited in claim 6 further comprising:
cancelling inversions and traversing said uninverted AND-tree of said initial value in response to said initial value being said inverted AND-tree;
propagating an inversion from a register output to a random input in response to said initial value not being said inverted AND-tree; and
merging random inputs to a constant valuer relative to a number of encountered inversions.

8. A computer program product for applying scalable formal coverage analysis to a testbench, the computer program product comprising one or more computer readable storage mediums having program code embodied therewith, the program code comprising programming instructions for:
selecting a set of properties proven unhittable in an original testbench to consider for coverage;
selecting and mutating one or more gates of a device under test of said original testbench, wherein a mutation property for said set of properties is introduced for each mutated gate of said device under test;
determining that a gate is covered in response to said mutation property being hittable while said gate is mutated; and
determining that said gate is uncovered in response to said mutation property being unhittable while said gate is mutated.

9. The computer program product as recited in claim 8, wherein a multiplexer is introduced between said gate and fan-out logic, wherein said multiplexer receives a random input and an output of said gate, wherein upon asserting a control signal to said multiplexer, said random input drives an output of said multiplexer thereby enabling mutation, wherein upon not asserting said control signal to said multiplexer, said output of said gate drives said output of said multiplexer.

10. The computer program product as recited in claim 9, wherein said set of properties is replaced for each mutated gate of said device under test and conjuncted with said control signal to enable said mutation.

11. The computer program product as recited in claim 8, wherein the program code further comprises the programming instructions for:
selecting a set of mutation nets comprising a subset of device under test inputs, outputs and gates;
computing a cone of influence for each mutation property of said set of properties;
removing one or more mutation nets of said set of mutation nets that are outside said cone of influence; and
building a two-model testbench to determine if said set of properties are covered in one or more mutation nets of said set of mutation nets that are not removed, wherein said two-model testbench comprises a first testbench for mutating a gate and a second testbench corresponding to said original testbench.

12. The computer program product as recited in claim 8, wherein mutation-selection logic statically nondeterministically selects among a set of possible mutations, wherein said selection is implemented by generating a random input vector to initialize a register vector that holds its value forever, which in turn is encoded as a one-hot vector, wherein each one-hot bit drives a control signal to multiplexors associated with said mutations.

13. The computer program product as recited in claim 8, wherein the program code further comprises the programming instructions for:
traversing an uninverted AND-tree rooted at a selected property;
traversing said uninverted AND-tree of an initial value of a register for each uninverted register encountered in said traversing of said uninverted AND-tree rooted at said selected property; and
determining if said initial value is an inverted AND-tree for each inverted register encountered in said traversing of said uninverted AND-tree rooted at said selected property.

14. The computer program product as recited in claim 13, wherein the program code further comprises the programming instructions for:
cancelling inversions and traversing said uninverted AND-tree of said initial value in response to said initial value being said inverted AND-tree;
propagating an inversion from a register output to a random input in response to said initial value not being said inverted AND-tree; and
merging random inputs to a constant valuer relative to a number of encountered inversions.

15. A system, comprising:
a memory for storing a computer program for applying scalable formal coverage analysis to a testbench; and
a processor connected to said memory, wherein said processor is configured to execute program instructions of the computer program comprising:
selecting a set of properties proven unhittable in an original testbench to consider for coverage;
selecting and mutating one or more gates of a device under test of said original testbench, wherein a mutation property for said set of properties is introduced for each mutated gate of said device under test;
determining that a gate is covered in response to said mutation property being hittable while said gate is mutated; and
determining that said gate is uncovered in response to said mutation property being unhittable while said gate is mutated.

16. The system as recited in claim 15, wherein a multiplexer is introduced between said gate and fan-out logic, wherein said multiplexer receives a random input and an output of said gate, wherein upon asserting a control signal to said multiplexer, said random input drives an output of said multiplexer thereby enabling mutation, wherein upon not asserting said control signal to said multiplexer, said output of said gate drives said output of said multiplexer.

17. The system as recited in claim 16, wherein said set of properties is replaced for each mutated gate of said device under test and conjuncted with said control signal to enable said mutation.

18. The system as recited in claim 15, wherein the program instructions of the computer program further comprise:
selecting a set of mutation nets comprising a subset of device under test inputs, outputs and gates;
computing a cone of influence for each mutation property of said set of properties;
removing one or more mutation nets of said set of mutation nets that are outside said cone of influence; and
building a two-model testbench to determine if said set of properties are covered in one or more mutation nets of said set of mutation nets that are not removed, wherein said two-model testbench comprises a first testbench for mutating a gate and a second testbench corresponding to said original testbench.

19. The system as recited in claim 15, wherein mutation-selection logic statically nondeterministically selects among a set of possible mutations, wherein said selection is implemented by generating a random input vector to initialize a register vector that holds its value forever, which in turn is encoded as a one-hot vector, wherein each one-hot bit drives a control signal to multiplexors associated with said mutations.

20. The system as recited in claim 15, wherein the program instructions of the computer program further comprise:
traversing an uninverted AND-tree rooted at a selected property;
traversing said uninverted AND-tree of an initial value of a register for each uninverted register encountered in said traversing of said uninverted AND-tree rooted at said selected property; and
determining if said initial value is an inverted AND-tree for each inverted register encountered in said traversing of said uninverted AND-tree rooted at said selected property.
